(19) United States
(12) Patent Application Publication
(10) Pub. No.: US 2014/0217369 A1
(43) Pub. Date: Aug. 7, 2014

(54) ORGANIC LIGHT-EMITTING TRANSISTOR

(71) Applicants: Dae Sung CHOI, Seongnam-si, (KR); Ki Seo KIM, Gongju-si, (KR); Yong Seok YEO, Seongnam-si, (KR)

(72) Inventors: Dae Sung CHOI, Seongnam-si, (KR); Ki Seo KIM, Gongju-si, (KR); Yong Seok YEO, Seongnam-si, (KR)

(21) Appl. No.: 13/937,965

(22) Filed: Jul. 9, 2013

(30) Foreign Application Priority Data
Feb. 6, 2013 (KR) 10-2013-0013458

(51) Int. Cl. H01L 51/52

(52) U.S. Cl. CPC H01L 51/5296
USPC 257/40

(57) ABSTRACT

An organic light-emitting transistor comprising a first electrode, a first semiconductor layer disposed on the first electrode, a second electrode disposed on the first semiconductor layer, a second semiconductor layer disposed on the second electrode, one of the first and second semiconductor layers having an organic semiconductor which emits light in response to a driving current that flows, and a third electrode disposed on the second semiconductor layer.

### CLAIM OF PRIORITY

This application makes reference to, incorporates the same herein, and claims all benefits accruing under 35 U.S.C. §119 from an application earlier filed in the Korean Intellectual Property Office on the 6 of Feb. 2013 and there duly assigned Serial No. 10-2013-0013458.

### BACKGROUND OF THE INVENTION

1. Field of the Invention

The present invention relates to an organic light-emitting transistor, and more particularly, to an organic light-emitting transistor having a vertical structure.

2. Description of the Related Art

An organic light-emitting transistor uses an organic material as a semiconductor device, whereas a conventional thin-film transistor (TFT) uses amorphous or polycrystalline silicon as a semiconductor device. As a p-type organic material used as a semiconductor in an organic light-emitting transistor, a multimer such as a conjugated polymer or thiophene, a metal phthalocyanine compound, a condensed aromatic hydrocarbon such as pentacene, etc. may be used alone or in mixture with another compound. As an n-type organic material, 1,4,5,8-naphthalenetetracarboxylic dianhydride (NTCDA), 11,11,12,12-tetracyanonaphthalene-2,6-quinodimethane (TCNNQD), 1,4,5,8-naphthalenetetracarboxylic diimide (NTCDI), fluorinated phthalocyanine, etc. may be used.

An organic light-emitting transistor may emit light in response to a current flowing between a source electrode and a drain electrode. Therefore, a display device can be formed using a plurality of organic light-emitting transistors. A display device using organic light-emitting transistors can advantageously be miniaturized, lightened, and thinned. In addition, since there are less restrictions on choice of substrates for an organic light-emitting transistor than for a conventional TFT, it is easy to realize a flexible display using organic light-emitting transistors.

Various organic light-emitting transistor structures have been suggested, including a sit induction transistor (SIT) structure, a metal insulator semiconductor (MIS) structure, and a metal oxide semiconductor (MOS) structure. However, the sit induction transistor (SIT) structure has a relatively limited light-emitting area, the metal insulator semiconductor (MIS) structure requires a relatively high voltage to be applied to a gate in order for operation, and the metal oxide semiconductor (MOS) structure requires a relatively high voltage to be applied between a source and a drain in order for operation.

### SUMMARY OF THE INVENTION

Aspects of the present invention provide an organic light-emitting transistor which can increase a light-emitting area.

Aspects of the present invention also provide an organic light-emitting transistor which can reduce a driving voltage.

However, aspects of the present invention are not restricted to the one set forth herein. The above and other aspects of the present invention will become more apparent to one of ordinary skill in the art to which the present invention pertains by referencing the detailed description of the present invention given below.

According to an aspect of the present invention, there is provided an organic light-emitting transistor comprising a first electrode, a first semiconductor layer disposed on the first electrode and comprising an organic semiconductor which emits light in response to a driving current that flows, a second electrode disposed on the first semiconductor layer, a second semiconductor layer disposed on the second electrode and a third electrode disposed on the second semiconductor layer.

According to another aspect of the present invention, there is provided an organic light-emitting transistor comprising a first electrode, a first semiconductor layer disposed on the first electrode, a second electrode disposed on the first semiconductor layer, a second semiconductor layer disposed on the second electrode and comprising an organic semiconductor which emits light in response to a driving current that flows and a third electrode disposed on the second semiconductor layer.

According to another aspect of the present invention, there is provided an organic light-emitting transistor comprising a first electrode, a semiconductor layer disposed on the first electrode and comprising an organic semiconductor which emits light in response to a driving current that flows, a second electrode disposed on the semiconductor layer, an electron transport layer disposed on the second electrode, and a third electrode disposed on the electron transport layer.

According to another aspect of the present invention, there is provided an organic light-emitting transistor comprising a first electrode, a hole transport layer disposed on the first electrode, a second electrode disposed on the hole transport layer, a semiconductor layer disposed on the second electrode and comprising an organic semiconductor which emits light in response to a driving current that flows, and a third electrode disposed on the semiconductor layer.

### BRIEF DESCRIPTION OF THE DRAWINGS

A more complete appreciation of the present invention, and many of the attendant advantages thereof, will become readily apparent as the same becomes better understood by reference to the following detailed description when considered in conjunction with the accompanying drawings in which like reference symbols indicate the same or similar components, wherein:

FIG. 1 is a cross-sectional view of an organic light-emitting transistor according to an embodiment of the present invention;

FIG. 2 is a diagram illustrating an energy band of each region of the organic light-emitting transistor shown in FIG. 1 when the organic light-emitting transistor is turned on;

FIGS. 3 and 4 are diagrams illustrating an energy band of each region of the organic light-emitting transistor shown in FIG. 1 when the organic light-emitting transistor is turned off;

FIG. 5 is a graph illustrating the relationship between a voltage of a second electrode and a current flowing through a first semiconductor layer in the organic light-emitting transistor of FIG. 1;

FIG. 6 is a cross-sectional view of an organic light-emitting transistor according to another embodiment of the present invention;

FIG. 7 is a cross-sectional view of an organic light-emitting transistor according to another embodiment of the present invention;

FIG. 8 is a cross-sectional view of an organic light-emitting transistor according to another embodiment of the present invention;

FIG. 9 is a cross-sectional view of an organic light-emitting transistor according to another embodiment of the present invention;

FIG. 10 is a cross-sectional view of an organic light-emitting transistor according to another embodiment of the present invention;

FIG. 11 is a cross-sectional view of an organic light-emitting transistor according to another embodiment of the present invention;

FIG. 12 is a cross-sectional view of an organic light-emitting transistor according to another embodiment of the present invention;

FIG. 13 is a cross-sectional view of an organic light-emitting transistor according to another embodiment of the present invention; and

FIG. 14 is a cross-sectional view of an organic light-emitting transistor according to another embodiment of the present invention.

### DETAILED DESCRIPTION OF THE INVENTION

Advantages and features of the present invention and methods of accomplishing the same may be understood more readily by reference to the following detailed description of preferred embodiments and the accompanying drawings. The present invention may, however, be embodied in many different forms and should not be construed as being limited to the embodiments set forth herein. Rather, these embodiments are provided so that this disclosure will be thorough and complete and will fully convey the concept of the invention to those skilled in the art, and the present invention will only be defined by the appended claims. Thus, in some embodiments, well-known structures and devices are not shown in order not to obscure the description of the invention with unnecessary detail. Like numbers refer to like elements throughout. In the drawings, the thickness of layers and regions are exaggerated for clarity.

It will be understood that when an element or layer is referred to as being “on,” or “connected to” another element or layer, it can be directly on or connected to the other element or layer or intervening elements or layers may be present. In contrast, when an element is referred to as being “directly on” or “directly connected to” another element or layer, there are no intervening elements or layers present. As used herein, the term “and/or” includes any and all combinations of one or more of the associated listed items.

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present invention.

Embodiments of the present invention will hereinafter be described with reference to the attached drawings.

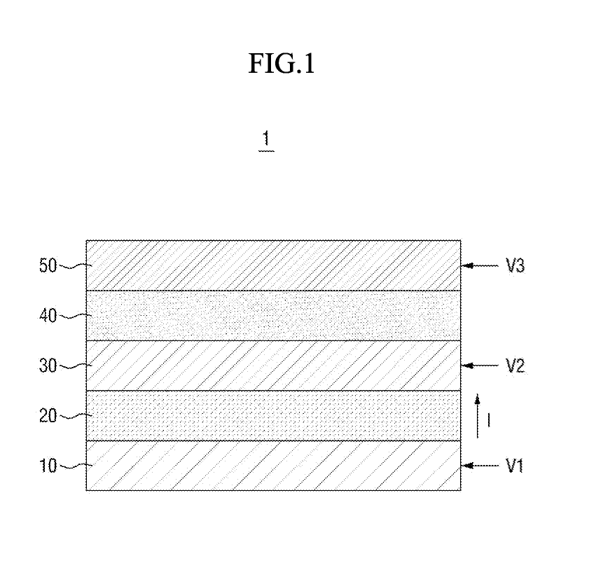

FIG. 1 is a cross-sectional view of an organic light-emitting transistor 1 according to an embodiment of the present invention.

Referring to FIG. 1, the organic light-emitting transistor 1 includes a first electrode 10, a first semiconductor layer 20, a second electrode 30, a second semiconductor layer 40, and a third electrode 50.

The first electrode 10 may be formed of a conductive material. A first voltage V1 may be applied to the first electrode 10. When the organic light-emitting transistor 1 is turned on, the first voltage V1 may be higher than a second voltage V2 applied to the second electrode 30 and a third voltage V3 applied to the third electrode 50. The first electrode 10 may be formed of a material with a higher work function than the material that forms the third electrode 50 in order to facilitate the injection of holes from the first electrode 10 toward the third electrode 50 when the organic light-emitting transistor 1 is turned on. The first electrode 10 may be formed of a transparent conductive material in order to emit light generated by the first semiconductor layer 20 in a downward direction. In an example, the first electrode 10 may be formed of, but not limited to, indium tin oxide (ITO), indium zinc oxide (IZO), a compound of magnesium (Mg) and silver (Ag), a compound of calcium (Ca) and Ag, or a compound of lithium (Li) and aluminum (Al). The first electrode 10 may function as a collector of the organic light-emitting transistor 1.

The first semiconductor layer 20 may be disposed on the first electrode 10. The first semiconductor layer 20 may have conductivity when the first voltage V1 is equal to or greater than the sum of the second voltage V2 and a second threshold voltage Vth2 which will be described later. The first semiconductor layer 20 may include an organic semiconductor. The organic semiconductor included in the first semiconductor layer 20 may be a p-type organic semiconductor which facilitates the transportation of holes emitted from the first electrode 10. The first semiconductor layer 20 may include an organic light-emitting material. The organic light-emitting material included in the first semiconductor layer 20 may emit light in response to an energy generated by the combination of holes emitted from the first electrode 10 and electrons emitted from the third electrode 50. In the first semiconductor layer 20, a driving current I may flow in a direction from the first electrode 10 toward the second electrode 30. The light emission luminance of the first semiconductor layer 20 may correspond to the driving current I. Since the first semiconductor layer 20 can emit light in response to the driving current I, a light-emitting region of the first semiconductor layer 20 may correspond to an overlap region of the first electrode 10 and the second electrode 30 through which the driving current I can flow easily. Therefore, the organic light-emitting transistor 1 can control the area of the light-emitting region by adjusting the overlap region of the first electrode 10 and the second electrode 30 and can easily realize a large-area light-emitting device.

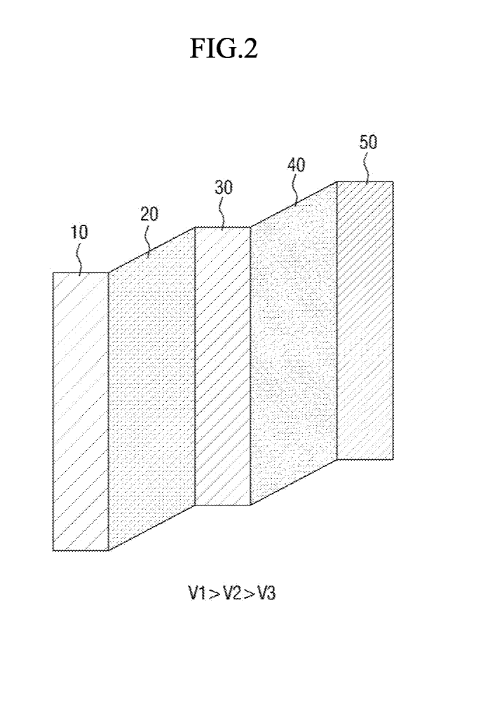

The second electrode 30 may be disposed on the first semiconductor layer 30. The second voltage V2 may be applied to the second electrode 30. The organic light-emitting transistor 1 can control its on-off state and light emission luminance by controlling the second voltage V2. This will be descried in more detail later with reference to FIGS. 2 through 5. The second electrode 30 may be formed of a conductive material. The second electrode 30 may be formed of a material with a lower work function than the material that forms the first electrode 10 and a higher work function than the material that forms the third electrode 50. The second electrode 30 may function as a base of the organic light-emitting transistor 1.

The second semiconductor layer 40 may be disposed on the second electrode 30. The second semiconductor layer 40 may include an n-type semiconductor in order to facilitate the transportation of electrons emitted from the third electrode 50. The second semiconductor layer 40 may be formed of an organic semiconductor or an inorganic semiconductor. The second semiconductor layer 40 may have conductivity when the second voltage V2 is equal to or greater than the sum of the third voltage V3 and a first threshold voltage Vth1.

The third electrode 50 may be disposed on the second semiconductor layer 40. The third voltage V3 may be applied to the third electrode 50. When the organic light-emitting transistor 1 is turned on, the third voltage V3 may be lower than the first voltage V1 and the second voltage V2. The third electrode 50 may be formed of a conductive material. The third electrode 50 may be formed of a material with a lower work function than the material that forms the first electrode 10 in order to facilitate the injection of electrons from the third electrode 50 toward the first electrode 10 when the organic light-emitting transistor 1 is turned on. The third electrode 50 may function as an emitter of the organic light-emitting transistor 1.

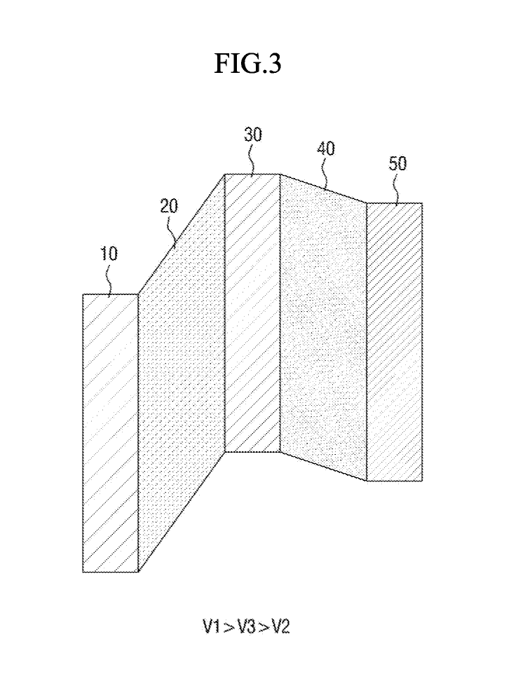

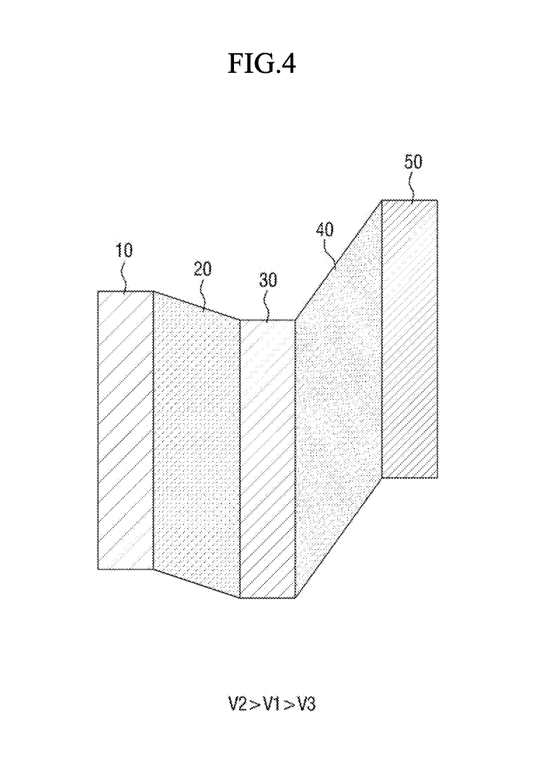

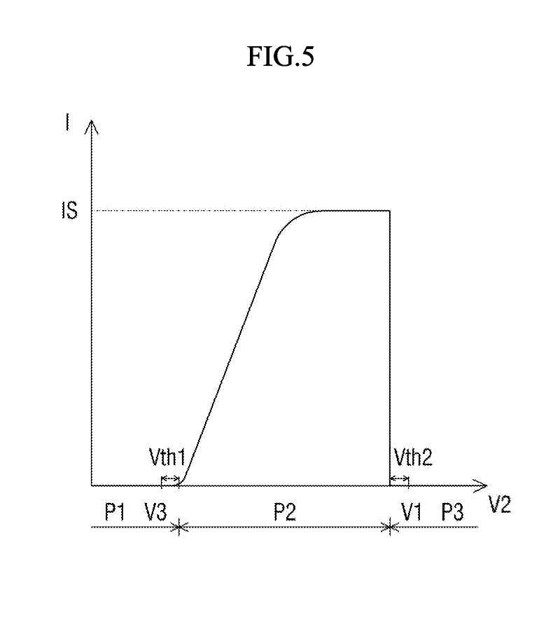

The operation of the organic light-emitting transistor 1 will now be described in detail with reference to FIGS. 2 through 5. FIG. 2 is a diagram illustrating an energy band of each region of the organic light-emitting transistor 1 shown in FIG. 1 when the organic light-emitting transistor 1 is turned on. FIGS. 3 and 4 are diagrams illustrating an energy band of each region of the organic light-emitting transistor 1 shown in FIG. 1 when the organic light-emitting transistor 1 is turned off. FIG. 5 is a graph illustrating the relationship between a voltage of the second electrode 30 and a current flowing through the first semiconductor layer 20 in the organic light-emitting transistor 1 of FIG. 1.

Referring to FIG. 2, when the first voltage V1 is greater than the second voltage V2 and when the second voltage V2 is greater than the third voltage V3, an energy level of the first electrode 10 may be lower than an energy level of the second electrode 30, and the energy level of the second electrode 30 may be lower than an energy level of the third electrode 50. Electrons may move from a place with a high energy level to a place with a low energy level, and holes may move from a place with a low energy level to a place with a high energy level. Therefore, when the energy level of the first electrode 10 is lower than the energy level of the second electrode 30 and when the energy level of the second electrode 30 is higher than the energy level of the third electrode 50 as illustrated in FIG. 2, holes may move smoothly from the first electrode 10 toward the third electrode 50, and electrons may move smoothly from the third electrode 50 toward the first electrode 10. As a result, the organic light-emitting transistor 1 may be turned on.

A turn-on period of the organic light-emitting transistor 1 will now be described in more detail with reference to FIG. 5. The organic light-emitting transistor 1 may be turned on when the second voltage V2 has a voltage value of a second period P2. The second period P2 may be a period in which the second voltage V2 is equal to or greater than the sum of the third voltage V3 and the first threshold voltage Vth1 and is equal to or smaller than a voltage obtained by subtracting the second threshold voltage Vth2 from the first voltage V1. The first threshold voltage Vth1 may be a minimum potential difference between the second electrode 30 and the third electrode 50 which is needed to overcome an energy barrier between the second semiconductor layer 40 and the third electrode 50. The second threshold voltage Vth2 may be a minimum potential difference between the second electrode 30 and the first electrode 10 which is needed to overcome an energy barrier between the first semiconductor layer 20 and the first electrode 10. In the second period P2, the driving current I may increase in response to an increase in the second voltage V2. In the second period P2, the driving current I may become a saturation current Is as the second voltage V2 increases. When the second voltage V2 is not greater than the sum of the third voltage V3 and the first threshold voltage Vth1, that is, in a first period P1, the energy barrier between the second semiconductor layer 40 and the third electrode 50 may not be overcome. Thus, the driving current I may not flow, and the organic light-emitting transistor 1 may not be turned on Likewise, when the second voltage V2 is not greater than the sum of the first voltage V1 and the second threshold voltage Vth2, that is, in a third period P3, the energy barrier between the first semiconductor layer 20 and the first electrode 10 may not be overcome. Thus, the driving current I may not flow, and the organic light-emitting transistor 1 may not be turned on.

Referring to FIG. 3, when the first voltage V1 is greater than the third voltage V3 and when the third voltage V3 is greater than the second voltage V2, the energy level of the first electrode 10 may be lower than the energy level of the second electrode 30, and the energy level of the second electrode 30 may be higher than the energy level of the third electrode 50. When the energy level of the second electrode 30 is higher than the energy level of the third electrode 50, electrons emitted from the third electrode 50 cannot move toward the second electrode 30. Thus, the driving current I cannot flow. Accordingly, the organic light-emitting transistor 1 is turned off.

Referring to FIG. 4, when the second voltage V2 is greater than the first voltage V1 and when the first voltage V1 is greater than the third voltage V3, the energy level of the first electrode 10 may be higher than the energy level of the second electrode 30, and the energy level of the second electrode 30 may be lower than the energy level of the third electrode 50. When the energy level of the first electrode 10 is higher than the energy level of the second electrode 30, holes emitted from the first electrode 10 cannot move toward the second electrode 30. Thus, the driving current I cannot flow. Accordingly, the organic light-emitting transistor 1 is turned off.

As described above with reference to FIGS. 2 through 5, to turn on the organic light-emitting transistor 1, the first voltage V1 should exceed the sum of the third voltage V3, the first threshold voltage Vth1 and the second threshold voltage Vth2. Therefore, the organic light-emitting transistor 1 can be driven only with a potential difference exceeding the first threshold voltage Vth1 and the second threshold voltage Vth2. That is, the organic light-emitting transistor 1 can be driven with a low voltage. In addition, when the second voltage V2 is equal to or greater than the sum of the third voltage V3 and the first threshold voltage Vth1 and is equal to or smaller than a voltage obtained by subtracting the second threshold voltage Vth2 from the first voltage V1, the organic light-emitting transistor 1 can be turned on. Therefore, the organic light-emitting transistor 1 can be driven with the second voltage V2 or a low voltage.

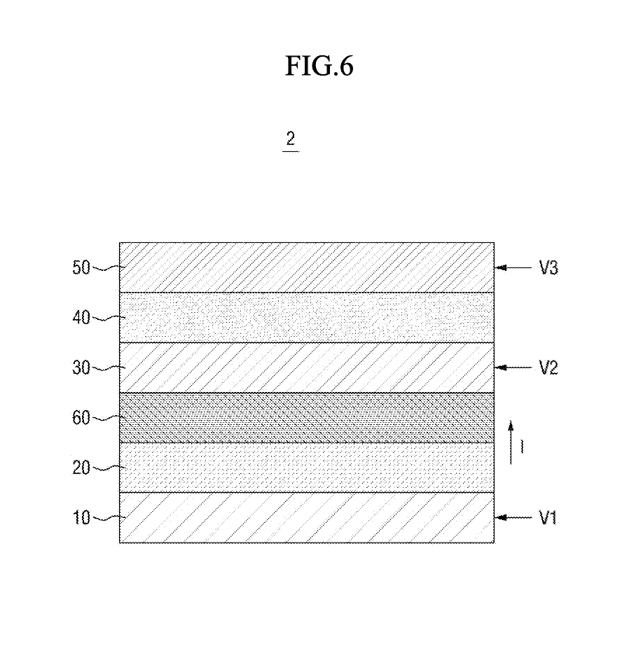

Another embodiment of the present invention will now be described with reference to FIG. 6. FIG. 6 is a cross-sectional view of an organic light-emitting transistor 2 according to another embodiment of the present invention.

For simplicity, other elements of the organic light-emitting transistor 2 substantially identical to those of the organic light-emitting transistor 1 of FIG. 1 are indicated by like reference numerals, and thus their description will be omitted.

Referring to FIG. 6, the organic light-emitting transistor 2 includes a first electrode 10, a first semiconductor layer 20, a second electrode 30, a second semiconductor layer 40, a third electrode 50, and a third semiconductor layer 60.

The third semiconductor layer 60 may be disposed between the first semiconductor layer 20 and the second electrode 30. The third semiconductor layer 60 may include an n-type semiconductor in order to transport electrons emitted from the third electrode 50 to the first semiconductor layer 20. The third semiconductor layer 60 may be formed of an organic semiconductor or an inorganic semiconductor. The third semiconductor layer 60 may not emit light in response to a driving current I. The third semiconductor layer 60 may control charge transfer characteristics of the organic light-emitting transistor 2.

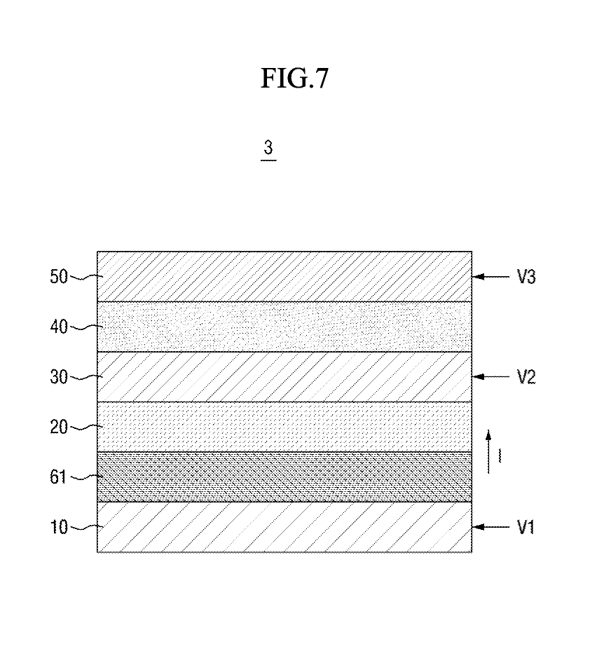

Another embodiment of the present invention will now be described with reference to FIG. 7. FIG. 7 is a cross-sectional view of an organic light-emitting transistor 3 according to another embodiment of the present invention.

For simplicity, other elements of the organic light-emitting transistor 3 substantially identical to those of the organic light-emitting transistor 1 of FIG. 1 are indicated by like reference numerals, and thus their description will be omitted.

Referring to FIG. 7, the organic light-emitting transistor 3 includes a first electrode 10, a first semiconductor layer 20, a second electrode 30, a second semiconductor layer 40, a third electrode 50, and a fourth semiconductor layer 61.

The fourth semiconductor layer 61 may be disposed between the first semiconductor layer 20 and the first electrode 10. The fourth semiconductor layer 61 may include a p-type semiconductor in order to transport holes emitted from the first electrode 10 to the first semiconductor layer 20. The fourth semiconductor layer 61 may be formed of an organic semiconductor or an inorganic semiconductor. The fourth semiconductor layer 61 may not emit light in response to a driving current I. The fourth semiconductor layer 61 may control charge transfer characteristics of the organic light-emitting transistor 3.

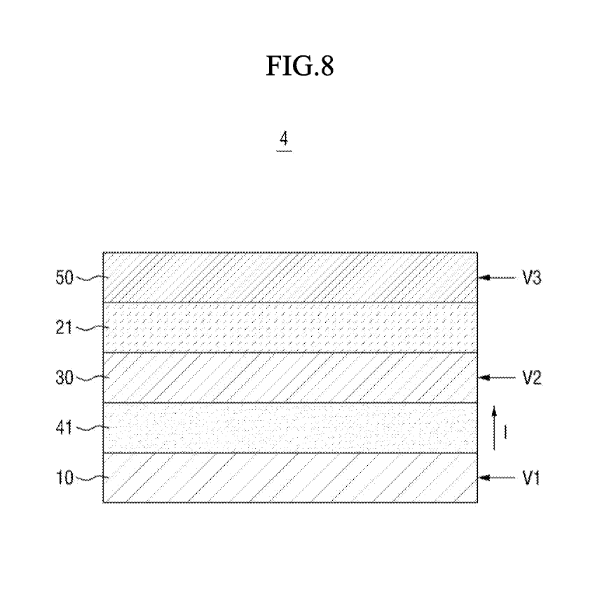

Another embodiment of the present invention will now be described with reference to FIG. 8. FIG. 8 is a cross-sectional view of an organic light-emitting transistor 4 according to another embodiment of the present invention.

For simplicity, other elements of the organic light-emitting transistor 4 substantially identical to those of the organic light-emitting transistor 1 of FIG. 1 are indicated by like reference numerals, and thus their description will be omitted.

Referring to FIG. 8, the organic light-emitting transistor 4 includes a first electrode 10, a second electrode 30, a third electrode 50, a first semiconductor layer 21, and a second semiconductor layer 41.

The second semiconductor layer 41 may be disposed on the first electrode 10. The second semiconductor layer 41 may include a p-type semiconductor in order to facilitate the transportation of holes emitted from the first electrode 10. The second semiconductor layer 41 may be formed of an organic semiconductor or an inorganic semiconductor. The second semiconductor layer 41 may have conductivity when a second voltage V2 is equal to or less than a value obtained by subtracting a second threshold voltage Vth2 from a first voltage V1.

The second electrode 30 may be disposed on the second semiconductor layer 41.

The first semiconductor layer 21 may be disposed on the second electrode 30. The first semiconductor layer 21 may have conductivity when the second voltage V2 is equal to or greater than the sum of a third voltage V3 and a first threshold voltage Vth1. The first semiconductor layer 21 may include an organic semiconductor. The organic semiconductor included in the first semiconductor layer 21 may be an n-type organic semiconductor which facilitates the transportation of electrons emitted from the third electrode 50. The first semiconductor layer 21 may include an organic light-emitting material. The organic light-emitting material included in the first semiconductor layer 21 may emit light in response to an energy generated by the combination of holes emitted from the first electrode 10 and electrons emitted from the third electrode 50. The light emission luminance of the first semiconductor layer 21 may correspond to a driving current I. A light-emitting region of the first semiconductor layer 21 may correspond to an overlap region of the second electrode 30 and the third electrode 50 through which the driving current I can flow easily. Therefore, the organic light-emitting transistor 4 can control the area of the light-emitting region by adjusting the overlap region of the second electrode 30 and the third electrode 50 and can easily realize a large-area light-emitting device.

The third electrode 50 may be disposed on the first semiconductor layer 21. The third electrode 50 may be formed of a transparent conductive material in order to emit light generated by the first semiconductor layer 21 in an upward direction. In an example, the third electrode 50 may be formed of, but not limited to, ITO, IZO, a compound of Mg and Ag, a compound of Ca and Ag, or a compound of Li and Al.

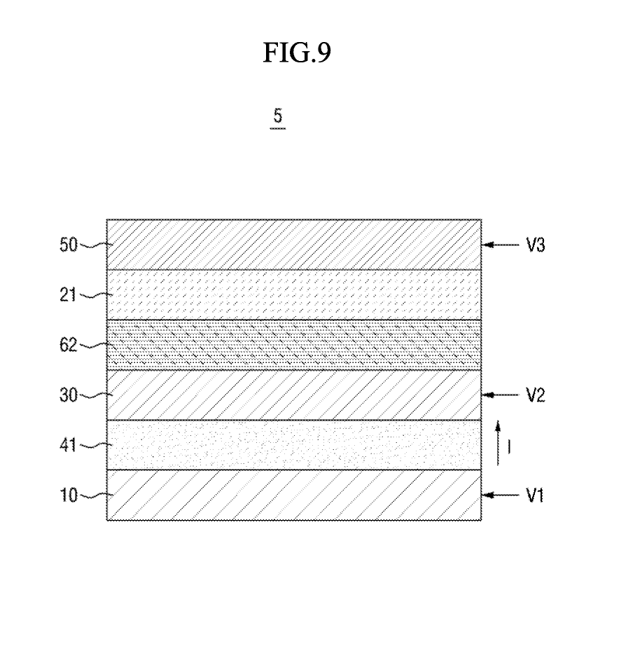

Another embodiment of the present invention will now be described with reference to FIG. 9. FIG. 9 is a cross-sectional view of an organic light-emitting transistor 5 according to another embodiment of the present invention.

For simplicity, other elements of the organic light-emitting transistor 5 substantially identical to those of the organic light-emitting transistor 4 of FIG. 8 are indicated by like reference numerals, and thus their description will be omitted.

Referring to FIG. 9, the organic light-emitting transistor 5 includes a first electrode 10, a second electrode 30, a third electrode 50, a first semiconductor layer 21, a second semiconductor layer 41, and a fifth semiconductor layer 62.

The fifth semiconductor layer 62 may be disposed between the second electrode 30 and the first semiconductor layer 21. The fifth semiconductor layer 62 may include a p-type semiconductor in order to transport holes emitted from the second electrode 30 to the first semiconductor layer 21. The fifth semiconductor layer 62 may be formed of an organic semiconductor or an inorganic semiconductor. The fifth semiconductor layer 62 may not emit light in response to a driving current I. The fifth semiconductor layer 62 may control charge transfer characteristics of the organic light-emitting transistor 5.

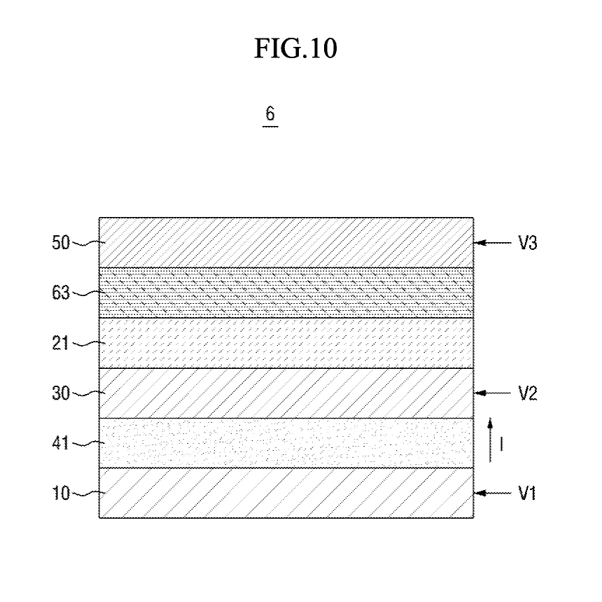

Another embodiment of the present invention will now be described with reference to FIG. 10. FIG. 10 is a cross-sectional view of an organic light-emitting transistor 6 according to another embodiment of the present invention.

For simplicity, other elements of the organic light-emitting transistor 6 substantially identical to those of the organic light-emitting transistor 4 of FIG. 8 are indicated by like reference numerals, and thus their description will be omitted.

Referring to FIG. 10, the organic light-emitting transistor 6 includes a first electrode 10, a second electrode 30, a third electrode 50, a first semiconductor layer 21, a second semiconductor layer 41, and a sixth semiconductor layer 63.

The sixth semiconductor layer 63 may be disposed between the third electrode 50 and the first semiconductor layer 21. The sixth semiconductor layer 63 may include an n-type semiconductor in order to transport electrons emitted from the third electrode 50 to the first semiconductor layer 21. The sixth semiconductor layer 63 may be formed of an organic semiconductor or an inorganic semiconductor. The sixth semiconductor layer 63 may not emit light in response to a driving current I. The sixth semiconductor layer 63 may control charge transfer characteristics of the organic light-emitting transistor 6.

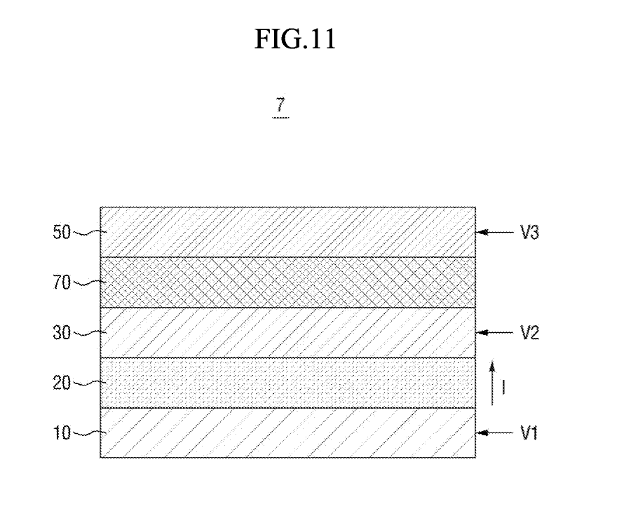

Another embodiment of the present invention will now be described with reference to FIG. 11. FIG. 11 is a cross-sectional view of an organic light-emitting transistor 7 according to another embodiment of the present invention.

For simplicity, other elements of the organic light-emitting transistor 7 substantially identical to those of the organic light-emitting transistor 1 of FIG. 1 are indicated by like reference numerals, and thus their description will be omitted.

Referring to FIG. 11, the organic light-emitting transistor 7 includes a first electrode 10, a second electrode 30, a third electrode 50, a first semiconductor layer 20, and an electron transport layer 70.

The electron transport layer 70 may be disposed between the second electrode 30 and the third electrode 50. The electron transport layer 70 may be formed of, but not limited to, Alq3, 4,7-diphenyl-1,10-phenanthroline (Bphen), 2-(4-Biphenyl)-5-(p-tert-butylphenyl)-1,3,4-oxadiazole (PBD), or carbon nanotubes. The electron transport layer 70 may move electrons emitted from the third electrode 50 toward the second electrode 30.

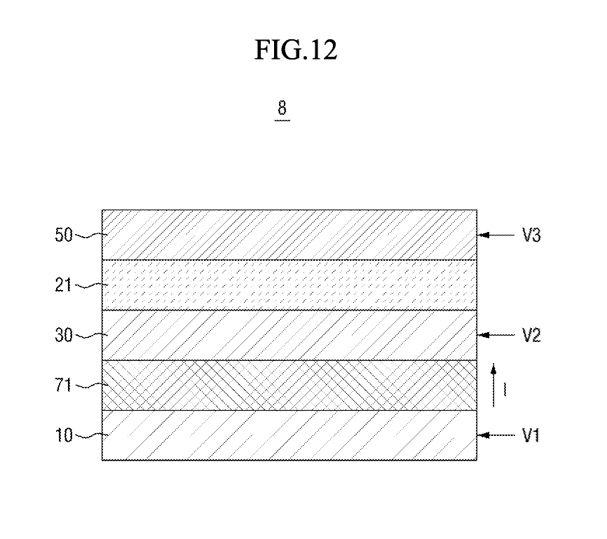

Another embodiment of the present invention will now be described with reference to FIG. 12. FIG. 12 is a cross-sectional view of an organic light-emitting transistor 8 according to another embodiment of the present invention.

For simplicity, other elements of the organic light-emitting transistor 8 substantially identical to those of the organic light-emitting transistor 4 of FIG. 8 are indicated by like reference numerals, and thus their description will be omitted.

Referring to FIG. 12, the organic light-emitting transistor 8 includes a first electrode 10, a second electrode 30, a third electrode 50, a first semiconductor layer 21, and a hole transport layer 71.

The hole transport layer 71 may be disposed between the first electrode 10 and the second electrode 30. The hole transport layer 71 may be formed of, but not limited to, 4,4′-bis [N-(1-naphthyl)-N-phenyl-mino]biphenyl (NPB) or N,N′-diphenyl-N,N′-bis (3-methylphenyl)-1,1-biphenyl-4,4′-diamine (TPD). The hole transport layer 71 may move holes emitted from the first electrode 10 toward the second electrode 30.

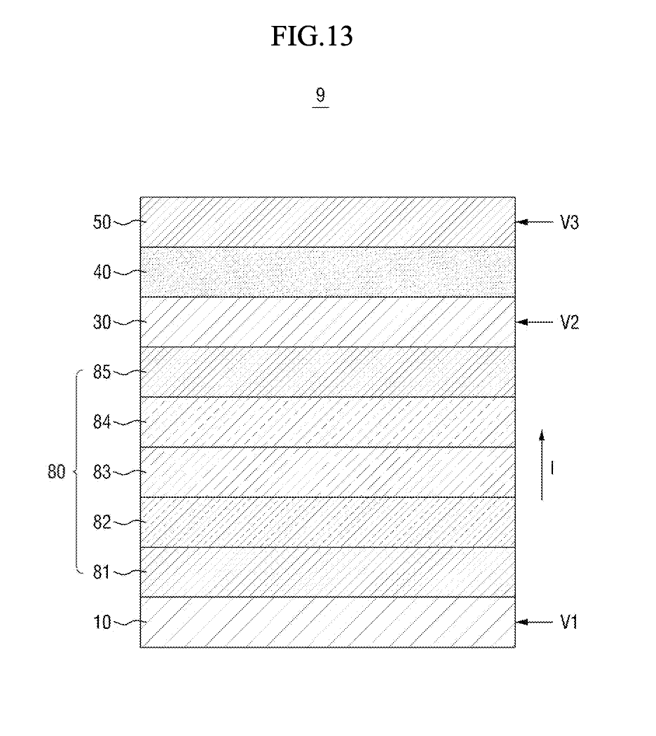

Another embodiment of the present invention will now be described with reference to FIG. 13. FIG. 13 is a cross-sectional view of an organic light-emitting transistor 9 according to another embodiment of the present invention.

For simplicity, other elements of the organic light-emitting transistor 9 substantially identical to those of the organic light-emitting transistor 1 of FIG. 1 are indicated by like reference numerals, and thus their description will be omitted.

Referring to FIG. 13, the organic light-emitting transistor 9 includes a first electrode 10, a second electrode 30, a third electrode 50, an organic light-emitting diode (OLED) 80, and a second semiconductor layer 40.

The OLED 80 may be disposed between the first electrode 10 and the second electrode 30. The OLED 80 may include a hole injection layer 81, a hole transport layer 82 disposed on the hole injection layer 81, an organic light-emitting layer 83 disposed on the hole transport layer 82, an electron transport layer 84 disposed on the organic light-emitting layer 83, and an electron injection layer 85 disposed on the electron transport layer 84. The organic light-emitting layer 83 may emit light at a luminance level corresponding to a driving current I. If the organic light-emitting transistor 9 includes the OLED 80 instead of the first semiconductor layer 20 of FIG. 1, since the OLED 80 includes the hole injection layer 81 which provides holes and the electron injection layer 85 which provides electrons, it is not necessary for the first electrode 10 and the third electrode to provide holes and electrons, respectively. Therefore, a work function does not need to be taken into consideration when selecting materials for the first electrode 10, the second electrode 30, and the third electrode 50.

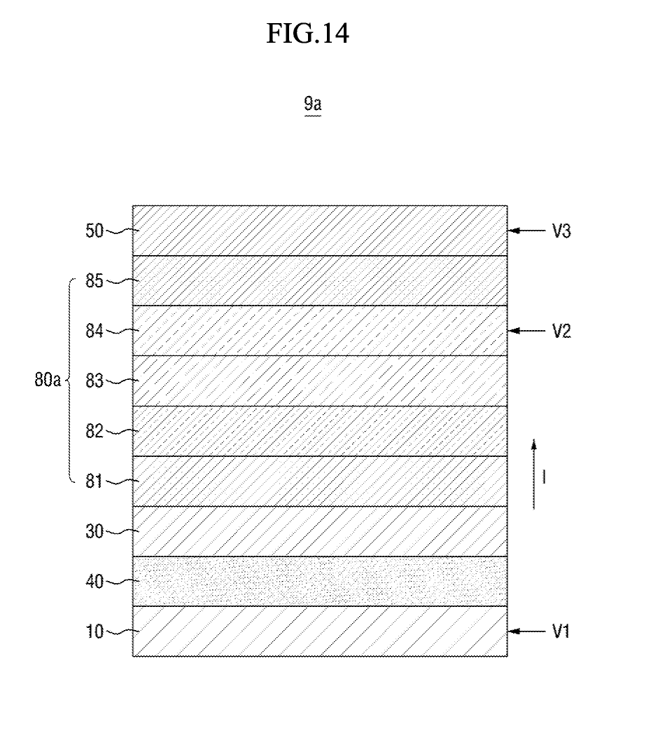

Another embodiment of the present invention will now be described with reference to FIG. 14. FIG. 14 is a cross-sectional view of an organic light-emitting transistor 9a according to another embodiment of the present invention.

For simplicity, other elements of the organic light-emitting transistor 9a substantially identical to those of the organic light-emitting transistor 4 of FIG. 8 are indicated by like reference numerals, and thus their description will be omitted.

Referring to FIG. 14, the organic light-emitting transistor 9a includes a first electrode 10, a second electrode 30, a third electrode 50, an OLED 80a, and a second semiconductor layer 40.

The OLED 80a may be disposed between the second electrode 30 and the third electrode 50. Other features of the OLED 80a are substantially identical to those of the OLED 80 described above with reference to FIG. 13, and thus a detailed description thereof will be omitted.

Embodiments of the present invention provide at least one of the following advantages.

That is, an organic light-emitting transistor with an increased light-emitting area can be provided.

In addition, an organic light-emitting transistor with a low driving voltage can be provided.

However, the effects of the present invention are not restricted to the one set forth herein. The above and other effects of the present invention will become more apparent to one of daily skill in the art to which the present invention pertains by referencing the claims.

1. An organic light-emitting transistor comprising:
a first electrode;
a first semiconductor layer disposed on the first electrode and comprising an organic semiconductor which emits light in response to a driving current that flows;
a second electrode disposed on the first semiconductor layer;
a second semiconductor layer disposed on the second electrode; and
a third electrode disposed on the second semiconductor layer.

2. The transistor of claim 1, wherein the second semiconductor layer comprises an organic semiconductor or an inorganic semiconductor.

3. The transistor of claim 1, wherein a first voltage is applied to the first electrode, a second voltage is applied to the second electrode, and a third voltage is applied to the third electrode, wherein when the organic light-emitting transistor is turned on, the second voltage is lower than the first voltage and higher than the third voltage.

4. The transistor of claim 3, being turned off when the second voltage is lower than the third voltage.

5. The transistor of claim 3, being turned off when the first voltage is higher than the third voltage and when the second voltage is higher than the first voltage.

6. The transistor of claim 1, further comprising a third semiconductor layer which is disposed between the first semiconductor layer and the first electrode.

7. The transistor of claim 1, further comprising a fourth semiconductor layer which is disposed between the first semiconductor layer and the second electrode.

8. The transistor of claim 1, wherein a work function of the first electrode is greater than that of the second electrode, and the work function of the second electrode is greater than that of the third electrode.

9. An organic light-emitting transistor comprising:
a first electrode;
a first semiconductor layer disposed on the first electrode;
a second electrode disposed on the first semiconductor layer;
a second semiconductor layer disposed on the second electrode and comprising an organic semiconductor which emits light in response to a driving current that flows; and
a third electrode disposed on the second semiconductor layer.

10. The transistor of claim 9, wherein a first voltage is applied to the first electrode, a second voltage is applied to the second electrode, and a third voltage is applied to the third electrode, wherein when the organic light-emitting transistor is turned on, the first voltage is higher than the third voltage, and the second voltage is lower than the first voltage and higher than the third voltage.

11. The transistor of claim 10, being turned off when the first voltage is higher than the third voltage and when the second voltage is lower than the third voltage.

12. The transistor of claim 10, being turned off when the first voltage is higher than the third voltage and when the second voltage is higher than the first voltage.

13. The transistor of claim 9, further comprising a third semiconductor layer which is disposed between the second semiconductor layer and the second electrode.

14. The transistor of claim 9, further comprising a fourth semiconductor layer which is disposed between the second semiconductor layer and the third electrode.

15. The transistor of claim 9, wherein a work function of the first electrode is greater than that of the second electrode, and the work function of the second electrode is greater than that of the third electrode.

16. An organic light-emitting transistor comprising:
a first electrode;
a semiconductor layer disposed on the first electrode and comprising an organic semiconductor which emits light in response to a driving current that flows;
a second electrode disposed on the semiconductor layer;
an electron transport layer disposed on the second electrode; and
a third electrode disposed on the electron transport layer.

17. The transistor of claim 16, wherein a first voltage is applied to the first electrode, a second voltage is applied to the second electrode, and a third voltage is applied to the third electrode, wherein when the organic light-emitting transistor is turned on, the first voltage is higher than the third voltage, and the second voltage is lower than the first voltage and higher than the third voltage.

18. The transistor of claim 17, being turned off when the first voltage is higher than the third voltage and when the second voltage is lower than the third voltage.

19. An organic light-emitting transistor comprising:
a first electrode;
a hole transport layer disposed on the first electrode;
a second electrode disposed on the hole transport layer;
a semiconductor layer disposed on the second electrode and comprising an organic semiconductor which emits light in response to a driving current that flows; and
a third electrode disposed on the semiconductor layer.

20. The transistor of claim 19, wherein a first voltage is applied to the first electrode, a second voltage is applied to the second electrode, and a third voltage is applied to the third electrode, wherein when the organic light-emitting transistor is turned on, the first voltage is higher than the third voltage, and the second voltage is lower than the first voltage and higher than the third voltage.
